(19) United States
(12) Patent Application Publication
(10) Pub. No.: US 2023/0126517 A1
(43) Pub. Date: Apr. 27, 2023

(54) COLOR CONVERSION PANEL AND DISPLAY DEVICE INCLUDING THE SAME

(71) Applicant: Samsung Display Co., LTD., Yongin-si (KR)

(72) Inventor: DOOHYUN LEE, Seongnam-si (KR)

(21) Appl. No.: 17/743,711

(22) Filed: May 13, 2022

(30) Foreign Application Priority Data
Oct. 25, 2021 (KR) 10-2021-0142665

(51) Int. Cl. H01L 27/32; G02B 5/20

(52) U.S. Cl. CPC H01L 27/322; H01L 27/3246; G02B 5/201; G02B 2207/113

(57) ABSTRACT

A color conversion panel of a display device includes a partition wall defining an opening and a groove which is in the partition wall and surrounds the opening, and a color conversion layer and a transmission layer within the opening which is defined by the partition wall.

This application claims priority to Korean Patent Application No. 10-2021-0142665 filed on Oct. 25, 2021, and all the benefits accruing therefrom under 35 U.S.C. § 119, the entire contents of which are incorporated herein by reference.

### BACKGROUND

### 1. Field

The present disclosure relates to a color conversion panel and a display device including the same.

### 2. Description of the Related Art

A display device serves to display an image via a display screen, and includes a liquid crystal display, an organic light emitting diode display, and the like. Such a display device is used in various electronic devices such as mobile phones, navigation units, digital cameras, electronic books, portable game machines, and various display terminals.

An organic light emitting diode display includes two electrodes and an organic light emitting layer positioned therebetween, and electrons injected from one of the two electrodes and holes injected from the other electrode are combined in the organic light emitting layer to form excitons. Excitons output energy and emit light while changing from an excited state to a ground state.

A display device including a color conversion panel has been proposed to reduce light loss and implement a display device with high color reproducibility. The color conversion panel may include a color conversion layer including semiconductor nanocrystals such as quantum dots, and may convert incident light into different colors. In addition, the color conversion layer may further include a light scatterer.

### SUMMARY

Within an electronic display apparatus, a color conversion layer of a color conversion panel may be divided by a partition wall. When a defect occurs in the partition wall, the color conversion layer penetrates into an adjacent region, and problems such as color mixing may occur. Embodiments have been made in an effort to provide a color conversion panel and a display device including the same, capable of firmly forming a partition wall.

An embodiment provides a color conversion panel including a first substrate, a partition wall on one side surface of the first substrate to include an opening and a groove, and a color conversion layer and a transmission layer within the opening of the partition wall, where the opening is surrounded by the groove in a plan view.

A depth of the groove may be about ⅓ or more and about ½ or less of a thickness of a portion of the partition wall in which the groove is not formed (e.g., thickness portion which is adjacent to the groove).

A thickness of a portion of the partition wall in which the groove may be formed (e.g., thickness portion which corresponds to the groove) may be about ½ or more and about ⅔ or less of a thickness of a portion of the partition wall in which the groove is not formed.

The thickness of the portion of the partition in which the groove may not be formed may be about 10 micrometers (μm) or more, the thickness of the portion of the partition in which the groove may be formed may be about 5 μm or more, and a thickness of the color conversion layer may be about 9 μm or more.

The opening may be surrounded by a plurality of grooves.

A volume of the groove may be about 23% or less of a volume of the color conversion layer.

According to the embodiment, the color conversion panel may further include a first color filter, a second color filter and a third color filter on the first substrate, the opening may include a first opening configured to overlap the first color filter, a second opening configured to overlap the second color filter, and a third opening configured to overlap the third color filter, the color conversion layer may include a first color conversion layer within the first opening and a second color conversion layer within the second opening, and the transmission layer is in the third opening.

The first opening may not overlap the second color filter and the third color filter, the second opening may not overlap the first color filter and the third color filter, and the third opening may not overlap the first color filter and the second color filter.

The partition wall may overlap at least one of the first color filter, the second color filter and the third color filter.

The opening may further include a fourth opening configured to overlap at least one of the first color filter, the second color filter and the third color filter.

The opening may further include a fifth opening between the second opening and the fourth opening, and a depth of the fifth opening may be greater than a depth of the groove.

An embodiment provides a display device including, a first substrate, a partition wall on one side surface of the first substrate to include an opening and a groove, a color conversion layer within the opening of the partition wall, a second substrate configured to face the first substrate, a transistor on a first side surface of the second substrate to face the first substrate, and an organic light emitting element connected to the transistor, where the opening is surrounded by the groove in a plan view.

A depth of the groove may be about ⅓ or more and about ½ or less of a thickness of a portion of the partition wall in which the groove is not formed.

A thickness of a portion of the partition wall in which the groove may be formed may be about ½ or more and about ⅔ or less of a thickness of a portion of the partition wall in which the groove is not formed.

The thickness of the portion of the partition in which the groove may not be formed may be about 10 μm or more, the thickness of the portion of the partition in which the groove may be formed may be about 5 μm or more, and the thickness of the color conversion layer may be about 9 μm or more.

The opening may be surrounded by a plurality of grooves.

A volume of the groove may be about 23% or less of a volume of the color conversion layer.

According to the embodiment, the display device may further include a first color filter, a second color filter and a third color filter on the first substrate, the opening may include a first opening configured to overlap the first color filter, a second opening configured to overlap the second color filter, and a third opening configured to overlap the third color filter, the color conversion layer may include a first color conversion layer within the first opening and a second color conversion layer within the second opening, and the transmission layer may be in the third opening.

The first opening may not overlap the second color filter and the third color filter, the second opening may not overlap the first color filter and the third color filter, and the third opening may not overlap the first color filter and the second color filter, and the partition wall may overlap at least one of the first color filter, the second color filter and the third color filter.

The opening may further include a fourth opening configured to overlap at least one of the first color filter, the second color filter and the third color filter, and a fifth opening between the second opening and the fourth opening, and a depth of the fifth opening may be greater than a depth of the groove.

According to the embodiments, a color conversion panel and a display device including the same may have a rigid partition wall structure.

### BRIEF DESCRIPTION OF THE DRAWINGS

The above and other advantages and features of this disclosure will become more apparent by describing in further detail embodiments thereof with reference to the accompanying drawings, in which:

FIG. 1 illustrates a schematic cross-sectional view of a display device according to an embodiment.

FIG. 2 illustrates a cross-sectional view showing a display device according to an embodiment.

FIG. 3 illustrates a top plan view showing a color conversion panel of a display device according to an embodiment.

FIG. 4 illustrates a cross-sectional view of a color conversion panel of a display device taken along line IV-IV′ of FIG. 3 according to an embodiment.

FIG. 5 illustrates a cross-sectional view of a color conversion panel of a display device taken along line V-V′ of FIG. 3 according to an embodiment.

FIG. 6 and FIG. 7 each illustrate a cross-sectional view showing a color conversion panel of a display device according to an example.

FIG. 8 illustrates a cross-sectional view showing a color conversion panel of a display device according to a comparative example.

FIG. 9 illustrates a top plan view showing a color conversion panel of a display device according to an embodiment.

FIG. 10 illustrates a top plan view showing a color conversion panel of a display device according to an embodiment.

FIG. 11 illustrates a cross-sectional view of a color conversion panel of a display device taken along line XI-XI′ of FIG. 10 according to an embodiment.

FIG. 12 illustrates a cross-sectional view of a color conversion panel of a display device taken along line XII-XII′ of FIG. 10 according to an embodiment.

### DETAILED DESCRIPTION

The invention will be described more fully hereinafter with reference to the accompanying drawings, in which embodiments of the invention are shown. As those skilled in the art would realize, the described embodiments may be modified in various different ways, all without departing from the spirit or scope of the invention.

To clearly describe the invention, parts that are irrelevant to the description are omitted, and like numerals refer to like or similar constituent elements throughout the specification. As used herein, a reference number may indicate a singular element or a plurality of the element. For example, a reference number labeling a singular form of an element within the drawing figures may be used to reference a plurality of the singular element within the text of specification.

Further, since sizes and thicknesses of constituent members shown in the accompanying drawings are arbitrarily given for better understanding and ease of description, the invention is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being related to another element such as being “on” another element, it can be directly on the other element or intervening elements may also be present. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Further, in the specification, the word “on” or “above” means positioned on or below the object portion, and does not necessarily mean positioned on the upper side of the object portion based on a gravitational direction.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. In addition, unless explicitly described to the contrary, the word “comprise” and variations such as “comprises” or “comprising” will be understood to imply the inclusion of stated elements but not the exclusion of any other elements.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Further, in the specification, the phrase “in a plan view” means when an object portion is viewed from above, and the phrase “in a cross-sectional view” means when a cross-section taken by vertically cutting an object portion is viewed from the side.

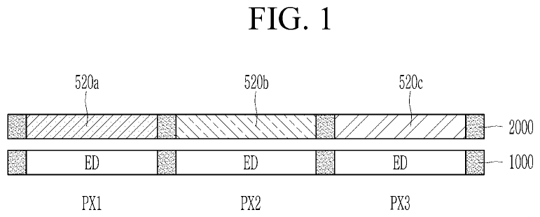

Hereinafter, a display device according to an embodiment will be described with reference to FIG. 1 to FIG. 5.

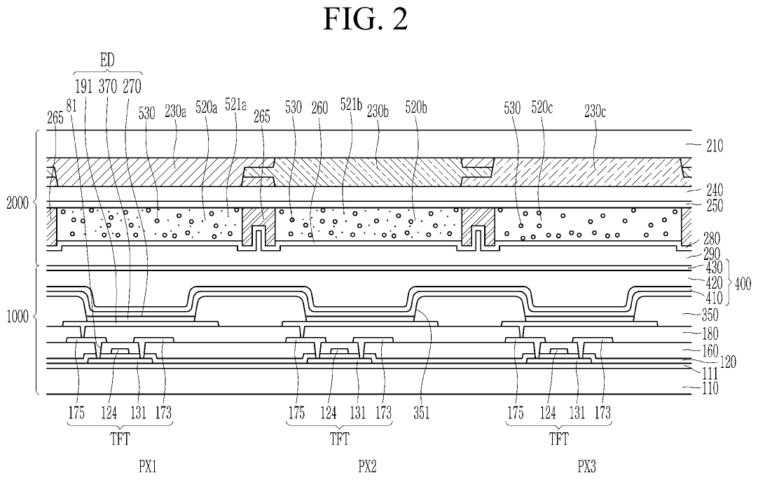

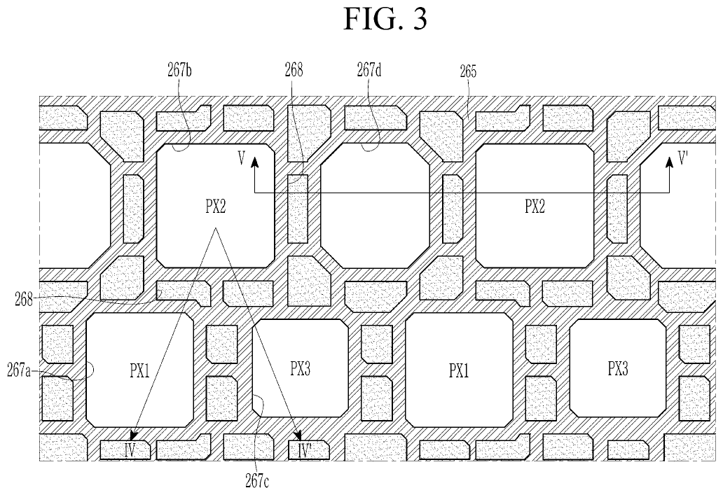

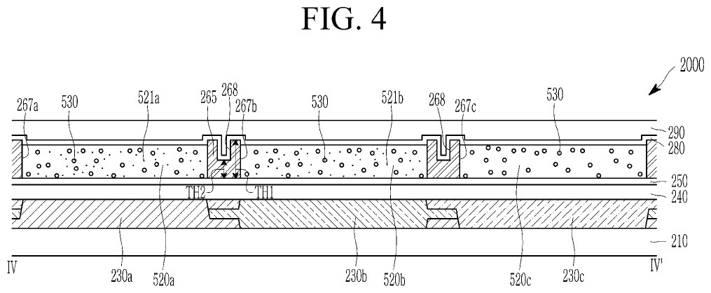

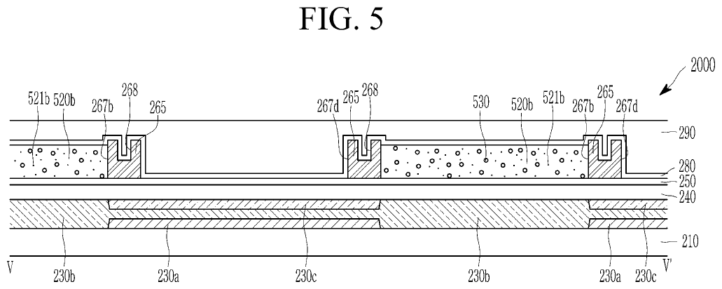

FIG. 1 illustrates a schematic cross-sectional view of a display device according to an embodiment, and FIG. 2 illustrates a cross-sectional view showing a display device according to an embodiment. FIG. 3 illustrates a top plan view showing a color conversion panel 2000 of a display device according to an embodiment, and FIG. 4 illustrates a cross-sectional view of a color conversion panel 2000 of a display device taken along line IV-IV′ of FIG. 3 according to an embodiment. FIG. 5 illustrates a cross-sectional view of a color conversion panel 2000 of a display device taken along line V-V′ of FIG. 3 according to an embodiment.

As illustrated in FIG. 1, the display device according to the present embodiment includes a display panel 1000 and a color conversion panel 2000 overlapping or facing each other. In a plan view, elements may be arranged along a first direction and/or a second direction crossing the first direction, such as to define a plane. A thickness of elements may be defined along a third direction crossing each of the first and second directions. A horizontal direction of FIG. 1 may represent the first direction and/or the second direction, while the vertical direction may represent a thickness direction (e.g., the third direction), without being limited thereto.

The display panel 1000 may include a plurality of pixels including a first pixel PX1 provided in plural including a plurality of first pixels PX1, a second pixel PX2 provided in plural including a plurality of second pixels PX2 and a third pixel PX3 provided in plural including a plurality of third pixels PX3, and a light emitting element may be positioned in each of the first pixel PX1, the second pixel PX2, and the third pixel PX3. That is, the display panel 1000 may include a plurality of light emitting diodes ED as light emitting elements. Each of the light emitting diodes ED may emit light, and the display panel 1000 may adjust the light emitted from the light emitting diodes ED of the first pixel PX1, the second pixel PX2, and the third pixel PX3, to generate light to display an image at a display screen of the display device.

The light emitting diode ED may be formed or provided as an organic light emitting element, and the display panel 1000 may be formed as an organic light emitting display panel. However, a type of the display panel 1000 is not limited thereto, and the display panel 1000 may be formed as various types of panels. In an embodiment, for example, the display panel 1000 may be formed as a liquid crystal display panel, an electrophoretic display panel, an electrowetting display panel, or the like. In addition, the display panel 1000 may be formed as a next-generation display panel such as a micro-LED (e.g., micro light emitting diode) display panel.

The display panel 1000 may be formed as a flat rigid display panel or a flexible display panel that can be flexibly bent.

The color conversion panel 2000 may be positioned to face the display panel 1000. The color conversion panel 2000 may include a light control layer including a first color conversion layer 520a, a second color conversion layer 520b, and a transmission layer 520c. The first color conversion layer 520a may overlap the light emitting diode ED positioned in the first pixel PX1. Light emitted from the light emitting diode ED of the first pixel PX1 may pass through the first color conversion layer 520a to emit light of a first wavelength. The second color conversion layer 520b may overlap the light emitting diode ED positioned in the second pixel PX2. Light emitted from the light emitting diode ED of the second pixel PX2 may pass through the second color conversion layer 520b to emit light of a second wavelength. The transmission layer 520c may overlap the light emitting diode ED positioned in the third pixel PX3. Light emitted from the light emitting diode ED of the third pixel PX3 may pass through the transmission layer 520c, such as without color conversion, to emit light of a third wavelength. In an embodiment, for example, the light of the first wavelength may be red light, the light of the second wavelength may be green light, and the light of the third wavelength may be blue light. That is, the first pixel PX1, the second pixel PX2, and the third pixel PX3 may be a red pixel, a green pixel, and a blue pixel, respectively. However, the invention is not limited thereto, and colors displayed by the first pixel PX1, the second pixel PX2, and the third pixel PX3 may be variously changed. In addition, a pixel displaying a different color may be further included in addition to the first pixel PX1, the second pixel PX2, and the third pixel PX3.

Hereinafter, a stacked structure of a display device according to an embodiment will be described with reference to FIG. 2 to FIG. 5.

In the display device according to an embodiment, the color conversion panel 2000 and the display panel 1000 are bonded to each other to face each other. In FIG. 2, the color conversion panel 2000 illustrated in FIG. 4 and FIG. 5 may be coupled to face the display panel 1000 in an upside-down state.

First, a stacked structure of the color conversion panel 2000 of a display device according to an embodiment will be described.

The color conversion panel 2000 may include a second substrate 210, and a first color filter 230a, a second color filter 230b and a third color filter 230c of a color filter layer which is positioned on one side of the second substrate 210.

The second substrate 210 may include a material having a rigid characteristic such as glass, or a flexible material such as plastic or polyimide that is bendable.

The first color filter 230a may transmit the light of the first wavelength and absorb light of remaining wavelengths other than the first wavelength, thereby increasing purity of the light of the first wavelength emitted to the outside of the display device.

The second color filter 230b may transmit the light of the second wavelength and absorb light of remaining wavelengths other than the second wavelength, thereby increasing purity of the light of the second wavelength emitted to the outside of the display device.

The third color filter 230c may transmit the light of the third wavelength and absorb light of remaining wavelengths other than the third wavelength, thereby increasing purity of the light of the third wavelength emitted to the outside of the display device.

The first color filter 230a, the second color filter 230b, and the third color filter 230c may be positioned to overlap the first pixel PX1, the second pixel PX2, and the third pixel PX3, respectively. The first color filter 230a, the second color filter 230b, and the third color filter 230c may overlap each other to form a light blocking region at a boundary between the first pixel PX1, the second pixel PX2, and the third pixel PX3. Although it is illustrated that the first color filter 230a, the second color filter 230b, and the third color filter 230c all overlap to define a light blocking region, the invention is not limited thereto. In an embodiment, for example, two of the first color filter 230a, the second color filter 230b, and the third color filter 230c may overlap to form a light blocking region. In an embodiment, for example, the first color filter 230a, and the second color filter 230b may overlap at a boundary between the first pixel PX1 and the second pixel PX2. The second color filter 230b and the third color filter 230c may overlap at a boundary between the second pixel PX2 and the third pixel PX3. The third color filter 230c and the first color filter 230a may overlap at a boundary between the third pixel PX3 and the first pixel PX1.

A low refractive index layer 240 may be positioned on first surfaces of the first color filter 230a, the second color filter 230b, and the third color filter 230c which are closest to the display panel 1000. That is, the low refractive index layer 240 may be positioned respectively between the first color filter 230a and the first color conversion layer 520a, between the second color filter 230b and the second color conversion layer 520b, and between the third color filter 230c and the transmission layer 520c. However, a position of the low refractive index layer 240 is not limited thereto, and may be variously changed. In an embodiment, for example, the low refractive index layer 240 may be positioned on the first color conversion layer 520a, the second color conversion layer 520b, and the transmission layer 520c, such as being closer to the light control layer than the color filter layer. Alternatively, the low refractive index layer 240 may include a plurality of layers, some of which are disposed between the first color filter 230a and the first color conversion layer 520a, between the second color filter 230b and the second color conversion layer 520b, and between the third color filter 230c and the transmission layer 520c, together with remaining layers positioned on the first color conversion layer 520a, the second color conversion layer 520b, and the transmission layer 520c. The low refractive index layer 240 may overlap all of the first color filter 230a, the second color filter 230b, and the third color filter 230c. That is, the low refractive index layer 240 may be positioned on an entirety of the second substrate 210, such as on an entirety of the second substrate 210.

The low refractive index layer 240 may include an organic material or an inorganic material having a low refractive index. In an embodiment, for example, the refractive index of the low refractive index layer 240 may be greater than or equal to about 1.1 and less than or equal to about 1.3.

A first capping layer 250 may be disposed on a surface of the low refractive index layer 240. The first capping layer 250, which is a layer for protecting the low refractive index layer 240, may include an inorganic insulating material such as a silicon nitride (SiNₓ), a silicon oxide (SiOₓ), or a silicon oxynitride (SiOₓN_{y}). The first capping layer 250 may have a single layer structure or a multi-layered structure of the material.

A partition wall 265 may be positioned on one side surface of the first capping layer 250, such as a lower surface closest to the display panel 1000. The partition wall 265 may be formed of or include a photosensitive resin. The partition wall 265 may include a colored pigment such as a black pigment or a blue pigment. The partition wall 265 may overlap a light blocking area where the first color filter 230a, the second color filter 230b, and the third color filter 230c overlap each other. The partition wall 265 may include or define openings 267a, 267b, 267c, and 267d and a groove 268 or a recess provided in plural including a plurality of grooves 268, to define a partition wall layer. The various openings are defined by solid portions of the partition wall 265, while the groove 268 is defined in various solid portions. The groove 268 is open in a direction towards the display panel 1000.

The openings 267a, 267b, 267c, and 267d of the partition wall 265 may include a first opening 267a, a second opening 267b, a third opening 267c, and a fourth opening 267d.

The first opening 267a may overlap an emission area of the first pixel PX1. The first opening 267a may overlap the first color filter 230a, and may not overlap (e.g., be spaced apart from) the second color filter 230b and the third color filter 230c. The second opening 267b may overlap an emission area of the second pixel PX2. The second opening 267b may overlap the second color filter 230b, and may not overlap the first color filter 230a and the third color filter 230c. The third opening 267c may overlap an emission area of the third pixel PX3. The third opening 267c may overlap the third color filter 230c, and may not overlap the first color filter 230a and the second color filter 230b. Accordingly, the partition wall 265 may have a shape surrounding the emission areas of the first pixel PX1, the second pixel PX2, and the third pixel PX3.

The fourth opening 267d may not overlap the first pixel PX1, the second pixel PX2, and the third pixel PX3. The fourth opening 267d may be positioned between the first pixel PX1, the second pixel PX2, and the third pixel PX3. The fourth opening 267d may overlap the first color filter 230a, the second color filter 230b, and the third color filter 230c. Although it is illustrated that the fourth opening 267d overlaps all of the first color filter 230a, the second color filter 230b, and the third color filter 230c, the invention is not limited thereto. The fourth opening 267d may overlap some of the first color filter 230a, the second color filter 230b, and the third color filter 230c. In an embodiment, for example, the fourth opening 267d may overlap the first color filter 230a and the second color filter 230b.

A planar shape of the openings 267a, 267b, 267c, and 267d may be appropriately changed depending on a planar shape of the first pixel PX1, the second pixel PX2, and the third pixel PX3. In an embodiment, for example, the second pixels PX2 may be positioned at an interval in a first row, and the first pixel PX1 and the third pixel PX3 may be alternately positioned at an interval in a second row. The second pixel PX2 may be positioned to be adjacent to the first pixel PX1 and the third pixel PX3, in a diagonal direction. Accordingly, the second opening 267b and the fourth opening 267d may be alternately positioned at an interval in the first row, and the first opening 267a and the third opening 267c may be alternately positioned at an interval in the second row.

The openings 267a, 267b, 267c, and 267d of the partition wall 265 are surrounded by grooves 268 in a plan view. The grooves 268 may be arranged along an outer edge or periphery of the various openings, and spaced apart from each other along the outer edge. Grooves 268 which surround a respective opening, may be common to the grooves 268 which surround an adjacent opening. In this case, one opening among the openings 267a, 267b, 267c, or 267d may be surrounded by the grooves 268 in a plane view. In an embodiment, for example, each of the first opening 267a, the second opening 267b, and the third opening 267c may be surrounded by ten grooves 268. The fourth opening 267d may be surrounded by eight grooves 268. However, this is only an example, and a number of grooves 268 surrounding each of the openings 267a, 267b, 267c, and 267d may be variously changed.

The openings 267a, 267b, 267c, and 267d of the partition wall 265 and the groove 268 may be simultaneously formed or provided with each other. The openings 267a, 267b, 267c, and 267d and the grooves 268 may be formed by coating a material for forming the partition wall 265 (e.g., partition wall material) on the first capping layer 250 and patterning the material using a slit mask or a halftone mask. During a patterning process, portions from which the material for forming the partition wall 265 is removed may define the openings 267a, 267b, 267c, and 267d, and a portion in which a thickness portion of the material for forming the partition wall 265 is reduced may define the groove 268.

A depth of the groove 268 along the thickness direction may be greater than or equal to about ⅓ of a first thickness TH1 of the portion of the solid portion of the partition wall 265 in which the groove 268 is not formed, and may be less than or equal to about ½ thereof. That is, a second thickness TH2 of the portion of the partition wall 265 corresponding to the groove 268 is about ½ or more of the first thickness TH1 of the portion of the partition wall 265 in which the groove 268 is not formed, and about ⅔ or less. In an embodiment, for example, the first thickness TH1 of the portion of the partition wall 265 in which the groove 268 is not formed may be about 10 micrometers (μm) or more, and the second thickness TH2 of the portion of the partition wall 265 corresponding to the groove 268 is formed may be about 5 μm or more.

The first color conversion layer 520a may be positioned in the first opening 267a, the second color conversion layer 520b may be positioned in the second opening 267b, and the transmission layer 520c may be positioned in the third opening 267c. A color conversion pattern (or layer) or a transmission pattern (or layer) may not be formed in the fourth opening 267d. The partition wall 265 along with the openings 267a, 267b, 267c, and 267d, the first color conversion layer 520a, the second color conversion layer 520b and the transmission layer 520c may defined a color control layer.

The openings 267a, 267b, 267c, and 267d and the grooves 268 may each have a volume, and the first color conversion layer 520a, the second color conversion layer 520b, or the transmission layer 520c may each occupy a volume. The first color conversion layer 520a, the second color conversion layer 520b, and the transmission layer 520c are surrounded by grooves 268 in a plan view. In this case, a volume occupied by one groove 268 may be about 23% of a volume occupied by at least one of the first color conversion layer 520a, the second color conversion layer 520b and the transmission layer 520c. The grooves 268 may be formed in different sizes. In an embodiment, for example, the volume of the grooves 268 surrounding the first color conversion layer 520a may be about 23% of the volume of the first color conversion layer 520a. Further, the volume of the grooves 268 surrounding the second color conversion layer 520b may be about 23% of the volume of the second color conversion layer 520b. In addition, the volume of the grooves 268 surrounding the transmission layer 520c may be about 23% of the volume of the transmission layer 520c. The volume of the grooves 268 may be determined by a product of a planar area of the grooves 268 and a depth of the grooves 268.

The first color conversion layer 520a may overlap the first color filter 230a. The first color conversion layer 520a may not overlap the second color filter 230b and the third color filter 230c. The first color conversion layer 520a may convert light incident from the light emitting diode ED of the first pixel PX1 into light having a first wavelength. In this case, the light of the first wavelength may be red light having a maximum emission peak wavelength of about 600 nanometers (nm) to about 650 nm, e.g., about 620 nm to about 650 nm. The first color conversion layer 520a may include a first quantum dot 521 provided in plural (e.g., a plurality of first quantum dots 521a) as a color conversion material layer, and a scatterer 530 provided in plural (e.g., a plurality of scatterers 530).

The second color conversion layer 520b may overlap the second color filter 230b. The second color conversion layer 520b may not overlap the first color filter 230a and the third color filter 230c. The second color conversion layer 520b may convert light incident from the light emitting diode ED of the second pixel PX2 into light having a second wavelength. In this case, the light of the second wavelength may be green light having a maximum emission peak wavelength of about 500 nm to about 550 nm, e.g., about 510 nm to about 550 nm. The second color conversion layer 520b may include a plurality of second quantum dots 521b as a color conversion material layer, and a plurality of scatterers 530.

The transmission layer 520c may overlap the third color filter 230c. The transmission layer 520c may not overlap the first color filter 230a and the second color filter 230b. The transmission layer 520c may transmit light incident from the light emitting diode ED of the third pixel PX3. The light passing through the transmission layer 520c may be light of a third wavelength. The light of the third wavelength may be blue light having a maximum emission peak wavelength of about 380 nm to about 480 nm, e.g., about 420 nm or more, about 430 nm or more, about 440 nm or more, or about 445 nm or more, and about 470 nm or less, about 460 nm or less, or about 455 nm or less. The transmission layer 520c may include a plurality of scatterers 530.

The scatterers 530 may scatter light incident to the first color conversion layer 520a, the second color conversion layer 520b, and the transmission layer 520c to improve light efficiency.

Each of the first quantum dots 521a and the second quantum dots 521b (hereinafter, also referred to as semiconductor nanocrystals) may independently include a Group II-VI compound, a Group III-V compound, a Group IV-VI compound, a Group IV element or compound, a Group compound, a Group compound, a Group I-II-IV-VI compound, or a combination thereof. The quantum dots may not contain cadmium.

The Group II-VI compound may be selected from a two-element compound selected from CdSe, CdTe, ZnS, ZnSe, ZnTe, ZnO, HgS, HgSe, HgTe, MgSe, MgS, and a combination thereof, a three-element compound selected from AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a combination thereof, and a four-element compound selected from HgZnTeS, CdZnSeS, CdZnSeTe, CdZnSTe, CdHgSeS, CdHgSeTe, CdHgSTe, HgZnSeS, HgZnSeTe, HgZnSTe, and a combination thereof. The Group II-VI compound may further include a Group III metal.

The Group III-V compound may be selected from a two-element compound selected from GaN, GaP, GaAs, GaSb, AlN, AlP, AlAs, AlSb, InN, InP, InAs, InSb, and a combination thereof, a three-element compound selected from GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and a combination thereof, and a four-element compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a combination thereof. The Group III-V compound may further include a group II metal (e.g., InZnP).

The Group IV-VI compound may be selected from a two-element compound selected from SnS, SnSe, SnTe, PbS, PbSe, PbTe, and a combination thereof, a three-element compound selected from SnSeS, SnSeTe, SnSTe, PbSeS, PbSeTe, PbSTe, SnPbS, SnPbSe, SnPbTe, and a combination thereof, and a four-element compound selected from SnPbSSe, SnPbSeTe, SnPbSTe, and a combination thereof.

The Group IV element or compound may be selected from a one-element compound selected from Si, Ge, and a combination thereof, and a two-element compound selected from SiC, SiGe, and a combination thereof, but the invention is not limited thereto.

Examples of the group compound are CuInSe₂, CuInS₂, CuInGaSe, and CuInGaS. Examples of the I-II-IV-VI group compound include, but are not limited to, CuZnSnSe and CuZnSnS. The Group IV element or compound may be selected from a one-element compound selected from Si, Ge, and a combination thereof, and a two-element compound selected from SiC, SiGe, and a combination thereof.

The Group compound may be selected from ZnGaS, ZnAlS, ZnInS, ZnGaSe, ZnAlSe, ZnTnSe, ZnGaTe, ZnAlTe, ZnTnTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and a combination thereof, but the invention is not limited thereto.

The Group I-II-IV-VI compound may be selected from CuZnSnSe and CuZnSnS, but the invention is not limited thereto.

In an embodiment, the quantum dots may not contain cadmium. The quantum dots may include semiconductor nanocrystals based on Group III-V compounds including indium and phosphorus. The Group III-V compound may further contain zinc. The quantum dots may include semiconductor nanocrystals based on a Group II-VI compound including a chalcogen element (e.g., sulfur, selenium, tellurium, or a combination thereof) and zinc.

In the quantum dots, the two-element compound, the three-element compound, and/or the four-element compound described above may be present in particles at uniform concentrations, or they may be divided into states having partially different concentrations to be present in the same particle, respectively. In addition, a core/shell structure in which some quantum dots surround some other quantum dots may be possible. An interface between the core and the shell may have a concentration gradient in which a concentration of elements of the shell decreases closer to a center thereof.

In embodiments, the quantum dot may have a core-shell structure that includes a core including the nanocrystal described above and a shell surrounding the core. The shell of the quantum dot may serve as a passivation layer for maintaining a semiconductor characteristic and/or as a charging layer for applying an electrophoretic characteristic to the quantum dot by preventing chemical denaturation of the core. The shell may be a single layer or a multilayer. An interface between the core and the shell may have a concentration gradient in which a concentration of elements of the shell decreases closer to a center thereof. An example of the shell of the quantum dot includes a metal or nonmetal oxide, a semiconductor compound, or a combination thereof.

Examples of an oxide of the metal or non-metal may include a two-element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a three-element compound such as MgAl₂O₄, CoFe₂O₄, NiFe₂O₄, or CoMn₂O₄. In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but the invention is not limited thereto.

An interface between the core and the shell may have a concentration gradient in which a concentration of elements of the shell decreases closer to a center thereof. In addition, the semiconductor nanocrystal may have a structure including one semiconductor nanocrystal core and a multilayered shell surrounding the semiconductor nanocrystal core. In an embodiment, the multilayered shell may have two or more layers, such as two, three, four, five, or more layers. The two adjacent layers of the shell can have a single composition or different compositions. Each layer in the multilayered shell may have a composition that varies depending on a radius.

The quantum dot may have a full width at half maximum (FWHM) of the light-emitting wavelength spectrum that is equal to or less than about 45 nm, such as equal to or less than about 40 nm, or such as equal to or less than about 30 nm, and in this range, color purity or color reproducibility may be improved. In addition, since light emitted through the quantum dot is emitted in all directions, a viewing angle of light may be improved.

In the quantum dot, a shell material and a core material may have different energy bandgaps. In an embodiment, for example, the energy bandgap of the shell material may be larger than that of the core material. In an embodiment, the energy bandgap of the shell material may be smaller than that of the core material. The quantum dot may have a multilayered shell. In the multilayered shell, the energy bandgap of an outer layer may be larger than that of an inner layer (i.e., a layer closer to the core). In the multilayered shell, the energy bandgap of the outer layer may be smaller than the energy bandgap of the inner layer.

The quantum dot may control an absorption/emission wavelength by controlling a composition and size thereof. A maximum emission peak wavelength of the quantum dot may have a wavelength range of ultraviolet rays to infrared rays or higher.

The quantum dot may include an organic ligand (e.g., having a hydrophobic moiety and/or a hydrophilic moiety). The organic ligand moiety may be bonded to a surface of the quantum dot. The organic ligand may include RCOOH, RNH₂, R₂NH, R₃N, RSH, R₃PO, R₃P, ROH, RCOOR, RPO(OH)₂, RHPOOH, R₂POOH, or a combination thereof, where each R may independently indicate a C3 to C40 (e.g., C5 or more and C24 or less) substituted or unsubstituted alkyl, a C3 to C40 substituted or unsubstituted aliphatic hydrocarbon group such as a substituted or unsubstituted alkenyl, a C6 to C40 (e.g., C6 or more and C20 or less) substituted or unsubstituted aromatic hydrocarbon group such as a substituted or unsubstituted C6 to C40 aryl group, or a combination thereof.

Examples of the organic ligand may include a thiol compound such as methane thiol, ethane thiol, propane thiol, butane thiol, pentane thiol, hexane thiol, octane thiol, dodecane thiol, hexadecane thiol, octadecane thiol, or benzyl thiol, an amine such as methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, dipropyl amine, tributylamine, and trioctylamine, a carboxylic acid compound such as methanic acid, ethanic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid, a phosphine compound such as methyl phosphine, ethyl phosphine, propyl phosphine, butyl phosphine, pentyl phosphine, octyl phosphine, dioctyl phosphine, tributylphosphine, trioctylphosphine, and the like, a phosphine compound or an oxide compound thereof such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, trioctyl phosphine oxide, diphenyl phosphine, a triphenyl phosphine compound, or an oxide compound thereof, or a C5 to C20 alkyl phosphinic acid such as hexylphosphinic acid, octylphosphinic acid, dodecanephosphinic acid, tetradecanephosphinic acid, hexadecanephosphinic acid, or octadecanephosphinic acid, but the invention is not limited thereto. The quantum dot may contain a hydrophobic organic ligand alone or as a combination of one or more. The hydrophobic organic ligand (e.g., an acrylate group, a methacrylate group, etc.) may not contain a photopolymerizable moiety.

A second capping layer 280 may be positioned on the first color conversion layer 520a, the second color conversion layer 520b, the transmission layer 520c, and the partition wall 265. The second capping layer 280 may be entirely disposed on the second substrate 210. The second capping layer 280 may extend from the first color conversion layer 520a, the second color conversion layer 520b, the transmission layer 520c, and the partition wall 265 and into the fourth opening 267d and the groove 268. Accordingly, the second capping layer 280 may also be disposed in the fourth opening 267d and the groove 268. The second capping layer 280 covers and protects the first color conversion layer 520a, the second color conversion layer 520b, and the transmission layer 520c, and may be made of or include an inorganic material. In an embodiment, for example, the second capping layer 280 may include an inorganic insulating material such as a silicon nitride (SiNₓ), a silicon oxide (SiOₓ), and a silicon oxynitride (SiOₓN_{y}). The second capping layer 280 may have a single layer structure or a multi-layered structure of the material.

A filling layer 290 may be positioned on the second capping layer 280. The filling layer 290 may be entirely disposed on the second substrate 210. The filling layer 290 is positioned between the display panel 1000 and the color conversion panel 2000 in a state where the display panel 1000 and the color conversion panel 2000 face each other and/or are bonded to each other. The filling layer 290 may extend from the first color conversion layer 520a, the second color conversion layer 520b, the transmission layer 520c, and the partition wall 265 and into the fourth opening 267d and the groove 268. The filling layer 290 may planarize the underlying layers.

Next, a stacked structure of the display panel 1000 of the display device according to an embodiment will be described.

The display panel 1000 may include a first substrate 110, a semiconductor 131 positioned on one side of the first substrate 110, a transistor TFT including a gate electrode 124, a source electrode 173, and a drain electrode 175, a gate insulating layer 120, a first interlayer insulating layer 160, a second interlayer insulating layer 180, a pixel electrode 191, an emission layer 370, a bank layer 350, a common electrode 270, and an encapsulation layer 400. The transistor TFT or the like may be positioned on one surface of the first substrate 110 of the display panel 1000 facing the second substrate 210 of the color conversion panel 2000 (e.g., closest to the color conversion panel 2000).

The first substrate 110 may include a material having a rigid characteristic such as glass, or a flexible material such as plastic or polyimide that is bendable. A buffer layer 111 for flattening a surface of the first substrate 110 and blocking impurities from penetrating into the semiconductor 131 may be further positioned on the first substrate 110. The buffer layer 111 may include an inorganic material, and for example, may include an inorganic insulating material such as a silicon nitride (SiNₓ), a silicon oxide (SiOₓ), and a silicon oxynitride (SiOₓN_{y}). The buffer layer 111 may have a single layer structure or a multilayer structure of the material. A barrier layer (not illustrated) may be further positioned on the first substrate 110. In this case, the barrier layer may be positioned between the first substrate 110 and the buffer layer 111. The barrier layer may include an inorganic insulating material such as a silicon nitride (SiNₓ), a silicon oxide (SiOₓ), and a silicon oxynitride (SiOₓN_{y}). The barrier layer may have a single layer structure or a multilayer structure of the material.

The semiconductor 131 may be positioned on the first substrate 110. The semiconductor 131 may include any one of amorphous silicon, polycrystalline silicon, and an oxide semiconductor. In an embodiment, for example, the semiconductor 131 may include low temperature polysilicon (LTPS), or may include an oxide semiconductor material including at least one of zinc (Zn), indium (In), gallium (Ga), tin (Sn), and a combination thereof. In an embodiment, for example, the semiconductor 131 may include an indium-gallium-zinc oxide (IGZO). The semiconductor 131 may include a channel region, a source region, and a drain region into which it is classified depending on whether or not it is doped with impurities. The source region and the drain region may have a conductive characteristic corresponding to a conductor.

The gate insulating layer 120 may cover the semiconductor 131 and the first substrate 110. The gate insulating layer 120 may include an inorganic insulating material such as a silicon nitride (SiNₓ), a silicon oxide (SiOₓ), and a silicon oxynitride (SiOₓN_{y}). The gate insulating layer 120 may have a single layer structure or a multilayer structure of the material.

The gate electrode 124 may be positioned on the gate insulating layer 120. The gate electrode 124 may include a metal such as copper (Cu), molybdenum (Mo), aluminum (Al), silver (Ag), chromium (Cr), or tantalum (Ta), or a metal alloy thereof. The gate electrode 124 may be formed as a single layer or a multilayer. A region of the semiconductor 131 that overlaps the planar gate electrode 124 may be a channel region.

The first interlayer insulating layer 160 may cover the gate electrode 124 and the gate insulating layer 120. The first interlayer insulating layer 160 may include an inorganic insulating material such as a silicon nitride (SiNₓ), a silicon oxide (SiOₓ), and a silicon oxynitride (SiOₓN_{y}). The first interlayer insulating layer 160 may have a single layer structure or a multilayer structure of the material.

The source electrode 173 and the drain electrode 175 are positioned on the first interlayer insulating layer 160. The source electrode 173 and the drain electrode 175 may be connected to the source region and the drain region of the semiconductor 131 through contact openings formed in the first interlayer insulating layer 160 and the gate insulating layer 120, respectively. The semiconductor 131, the gate electrode 124, the source electrode 173, and the drain electrode 175 described above constitute one thin film transistor TFT. According to an embodiment, the transistor TFT may include only the source region and the drain region of the semiconductor 131 instead of the source electrode 173 and the drain electrode 175. Although one transistor TFT is illustrated in each of the first pixel PX1, the second pixel PX2, and the third pixel PX3, the invention is not limited thereto, and a plurality of transistors TFTs may be positioned in each of the first pixel PX1, the second pixel PX2, and the third pixel PX3.

The source electrode 173 and the drain electrode 175 may include a metal such as aluminum (Al), copper (Cu), silver (Ag), gold (Au), platinum (Pt), palladium (Pd), nickel (Ni), molybdenum (Mo), tungsten (W), titanium (Ti), chromium (Cr), tantalum (Ta), or the like, or a metal alloy thereof. The source electrode 173 and the drain electrode 175 may be formed as a single layer or a multilayer. The source electrode 173 and the drain electrode 175 according to an embodiment may be configured as a triple layer including an upper layer, an intermediate layer, and a lower layer, the upper layer and the lower layer may include titanium (Ti), and the intermediate layer may include aluminum (Al).

The second interlayer insulating layer 180 may be positioned on the source electrode 173 and the drain electrode 175. The second interlayer insulating layer 180 covers the source electrode 173, the drain electrode 175, and the first interlayer insulating layer 160. The second interlayer insulating layer 180, which is for planarizing a surface of the first substrate 110 provided with the transistor TFT, may be an organic insulating layer, and may include at least one material of a polyimide, a polyamide, an acrylic resin, benzocyclobutene, and a phenol resin.

The pixel electrode 191 may be positioned on the second interlayer insulating layer 180. The pixel electrode 191 is also referred to as an anode or first electrode, and may be formed as a single layer including a transparent conductive oxide film or a metal material or as multiple layers including them. The transparent conductive oxide layer may include an indium tin oxide (ITO), a poly-ITO, an indium zinc oxide (IZO), an indium gallium zinc oxide (IGZO), an indium tin zinc oxide (ITZO), and the like. The metal material may include silver (Ag), molybdenum (Mo), copper (Cu), gold (Au), and aluminum (Al).

The second interlayer insulating layer 180 may include a via hole 81 exposing the drain electrode 175 to outside the second interlayer insulating layer 180. The drain electrode 175 and the pixel electrode 191 may be physically and electrically connected at or through the via hole 81 of the second interlayer insulating layer 180. Accordingly, the pixel electrode 191 can receive an output current (e.g., electrical current) to be transferred from the drain electrode 175 to the emission layer 370.

The bank layer 350 may be positioned on the pixel electrode 191 and the second interlayer insulating layer 180. The bank layer 350 is also referred to as a pixel defining layer (PDL), and has a pixel opening 351 overlapping at least a portion of the pixel electrode 191. In this case, the pixel opening 351 may overlap a central portion of the pixel electrode 191, and may not overlap an edge portion of the pixel electrode 191. As a result, a size of the pixel opening 351 may be smaller than that of the pixel electrode 191. The bank layer 350 may define a formation position of the emission layer 370 such that the emission layer 370 may be positioned on a portion thereof where an upper surface of the pixel electrode 191 which is closest to the color conversion panel 2000 is exposed to outside the bank layer 350. The bank layer 350 may be formed as an organic insulator including at least one material of a polyimide, a polyamide, an acryl resin, benzocyclobutene, and a phenol resin. According to an embodiment, the bank layer 350 may also be formed as a black pixel defining layer (BPDL) including a black pigment.

The bank layer 350 may be positioned at a boundary between adjacent pixels among the first pixel PX1, the second pixel PX2, and the third pixel PX3. The bank layer 350 may overlap the partition wall 265. In addition, the bank layer 350 may overlap a light blocking area where the first color filter 230a, the second color filter 230b, and the third color filter 230c overlap each other.

Each of the pixel openings 351 may have a planar shape similar to that of the pixel electrode 191 in a plan view. In an embodiment, for example, the pixel opening 351 and the pixel electrode 191 may have a polygonal shape in a plan view. In this case, corner portions of the pixel opening 351 and the pixel electrode 191 may be chamfered or curved. However, a shape of the pixel opening 351 and a shape of the pixel electrode 191 are not limited thereto, and may be variously changed.

In this case, a plurality of pixel electrodes 191 corresponding to each of the first pixel PX1, the second pixel PX2, and the third pixel PX3 may have different sizes in a plan view. Similarly, the pixel openings 351 corresponding to each of the first pixel PX1, the second pixel PX2, and the third pixel PX3 may have different sizes in a plan view. In an embodiment, for example, the pixel opening 351 and the pixel electrode 191 corresponding to the first pixel PX1 may respectively have larger sizes than the pixel opening 351 and the pixel electrode 191 corresponding to the second pixel PX2 in a plan view. In addition, the pixel opening 351 and the pixel electrode 191 corresponding to the first pixel PX1 may respectively have sizes that are smaller than or similar to the pixel opening 351 and the pixel electrode 191 corresponding to the third pixel PX3 in a plan view. However, the invention is not limited thereto, and each of the pixel openings 351 and the pixel electrodes 191 may be set to have various sizes.

The emission layer 370 may be disposed within the pixel opening 351 defined by the bank layer 350. The emission layer 370 may include a low molecular weight or a high molecular weight organic material. Although the emission layer 370 is illustrated as a single layer, actually, auxiliary layers such as an electron injection layer, an electron transport layer, a hole transport layer, and a hole injection layer may also be included above and below the emission layer 370. A hole injection layer and a hole transport layer may be positioned under the emission layer 370, and an electron transport layer and an electron injection layer may be positioned above the emission layer 370. In addition, another emission layer may be further positioned on the emission layer 370. That is, two or more emission layers 370 may be stacked.

Although not illustrated, a spacer may be further positioned on the bank layer 350. The spacer may include a same material as that of the bank layer 350. However, the invention is not limited thereto, and the spacer may be made of a material that is different from that of the bank layer 350. The spacer may be formed as an organic insulator including at least one material of a polyimide, a polyamide, an acryl resin, benzocyclobutene, and a phenol resin.

The common electrode 270 may be positioned on the bank layer 350 and the emission layer 370. The common electrode 270 of the first pixel PX1, the second pixel PX2, and the third pixel PX3 may be connected to each other in a single layer. The common electrode 270 may be positioned on the first substrate 110 to be entirely disposed thereon. The common electrode 270 may be referred to as a cathode or second electrode, and may be formed of a transparent conductive layer including an indium tin oxide (ITO), an indium zinc oxide (IZO), an indium gallium zinc oxide (IGZO), an indium tin zinc oxide (ITZO), etc. The common electrode 270 may be made of a metal material such as silver (Ag), magnesium (Mg), or the like, or a combination thereof. In this case, the thickness of the common electrode 270 may be adjusted to form a transparent conductive layer. In addition, the common electrode 270 may have a translucent characteristic, and in this case, may constitute a micro-cavity together with the pixel electrode 191.

The pixel electrode 191, the emission layer 370, and the common electrode 270 may constitute a light emitting diode ED. A portion where the pixel electrode 191, the emission layer 370, and the common electrode 270 overlap may be an emission area of each light emitting diode ED in the first pixel PX1, the second pixel PX2, and the third pixel PX3.

The light emitting diode ED positioned in the first pixel PX1 may overlap the first color conversion layer 520a and the first color filter 230a. The light emitting diode ED positioned in the first pixel PX1 may not overlap the second color conversion layer 520b, the transmission layer 520c, the second color filter 230b, and the third color filter 230c. Light emitted from the light emitting diode ED of the first pixel PX1 may be converted into light of a first wavelength while passing through the first color conversion layer 520a, and may be emitted to the outside (e.g., outside of the color conversion panel 2000) through the first color filter 230a.

The light emitting diode ED positioned in the second pixel PX2 may overlap the second color conversion layer 520b and the second color filter 230b. The light emitting diode ED positioned in the second pixel PX2 may not overlap the first color conversion layer 520a, the transmission layer 520c, the first color filter 230a, and the third color filter 230c. Light emitted from the light emitting diode ED of the second pixel PX2 may be converted into light of a second wavelength while passing through the second color conversion layer 520b, and may be emitted through the second color filter 230b to the outside.

The light emitting diode ED positioned in the third pixel PX3 may overlap the transmission layer 520c and the third color filter 230c. The light emitting diode ED positioned in the third pixel PX3 may not overlap the first color conversion layer 520a, the second color conversion layer 520b, the first color filter 230a, and the second color filter 230b. Light of the third wavelength emitted from the light emitting diode ED of the third pixel PX3 may pass through the transmission layer 520c and the first color filter 230a in order to be emitted to the outside.

The encapsulation layer 400 may be disposed on the common electrode 270. The encapsulation layer 400 may include at least one inorganic layer and at least one organic layer. In the present embodiment, the encapsulation layer 400 may include a first inorganic encapsulation layer 410, an organic encapsulation layer 420, and a second inorganic encapsulation layer 430. However, this is merely an example, and numbers of inorganic and organic layers constituting the encapsulation layer 400 may be variously changed. In an embodiment, for example, the encapsulation layer 400 may include a first inorganic layer, a second inorganic layer, a first organic layer, and a third inorganic layer stacked in that order, such as in a direction away from the display panel 1000. Alternatively, the encapsulation layer 400 may include the first inorganic layer, the first organic layer, the second inorganic layer, and the third inorganic layer stacked in that order.

The display panel 1000 may include a display area for displaying a display screen and a peripheral area which surrounds the display area. The first inorganic encapsulation layer 410, the organic encapsulation layer 420, and the second inorganic encapsulation layer 430 may be disposed in a portion of the display area and the peripheral area. According to an embodiment, the organic encapsulation layer 420 may be formed around the display area, and the first inorganic encapsulation layer 410 and the second inorganic encapsulation layer 430 may be formed up to the peripheral area. The encapsulation layer 400, which is for protecting the light emitting diode ED from moisture or oxygen that may be introduced from the outside, may be formed to directly contact first ends of the first inorganic encapsulation layer 410 and the second inorganic encapsulation layer 430, such as in the peripheral area. As being in contact, elements may form an interface with each other, without being limited thereto.

The encapsulation layer 400 may be in contact with the color conversion panel 2000. The encapsulation layer 400 may be in contact with the color conversion panel 2000 at the filling layer 290. The second inorganic encapsulation layer 430 may be in contact with the filling layer 290. However, this is merely an example, and another layer may be further positioned between the encapsulation layer 400 and the filling layer 290.

Although not illustrated, the display device according to an embodiment may further include a sensing unit for sensing a touch. The sensing unit (or sensing layer) may include a plurality of sensing electrodes, and the sensing layer may be positioned between the display panel 1000 and the color conversion panel 2000.

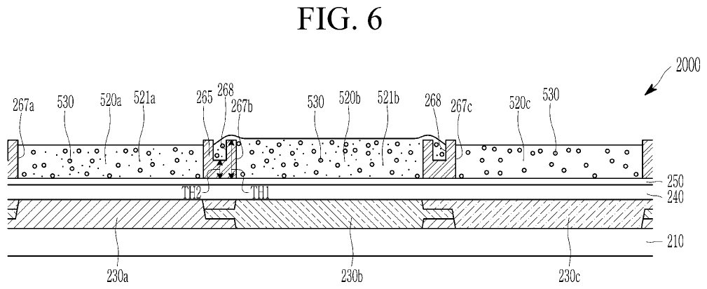

Hereinafter, an effect of having a structure including a groove 268 in a partition wall 265 of a color conversion panel 2000 of a display device according to an embodiment will be described with reference to FIG. 6 to FIG. 8.

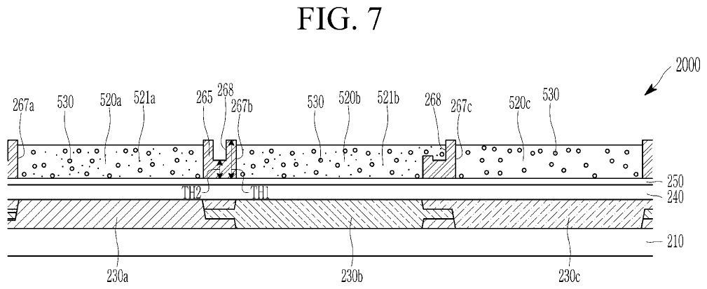

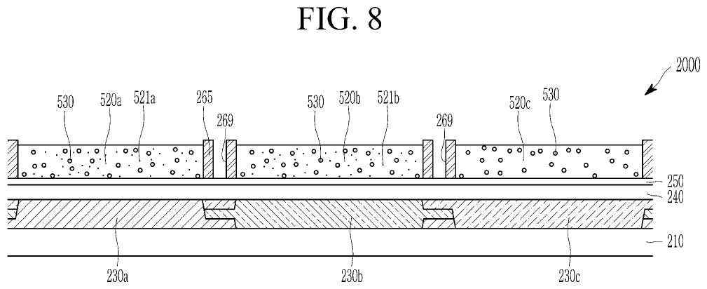

FIG. 6 and FIG. 7 each illustrate a cross-sectional view showing a color conversion panel 2000 of a display device according to an example, and FIG. 8 illustrates a cross-sectional view showing a color conversion panel 2000 of a display device according to a comparative example.

As illustrated in FIG. 6, overfilling of material may occur in a process of forming the first color conversion layer 520a, the second color conversion layer 520b, and the transmission layer 520c during a process of manufacturing a color conversion panel 2000 of a display device according to an embodiment. The first color conversion layer 520a, the second color conversion layer 520b, and the transmission layer 520c may be formed by inkjet printing. In the inkjet printing, a nozzle may be fixed to a head of an inkjet printing apparatus, and ink may be discharged from the nozzle while the head is moved. The discharged ink may fall into the first opening 267a, the second opening 267b, and the third opening 267c to form the first color conversion layer 520a, the second color conversion layer 520b, and the transmission layer 520c, respectively. In this case, an amount of ink dripping within the first opening 267a, the second opening 267b, and the third opening 267c is preset, but in some cases, an error may occur so that the ink may be insufficiently filled or overfilled.

In an embodiment, for example, a thickness of the partition wall 265 may be designed to be about 10 μm or more, and a thickness of the second color conversion layer 520b filling the second opening 267b may be designed to be about 9 μm or more. In this case, the ink material for forming the second color conversion layer 520b may be sufficiently dripped to fill the second opening 267b. Since the partition wall 265 of the color conversion panel 2000 of the display device according to an embodiment includes the grooves 268 surrounding the second opening 267b, the second opening 267b may receive the ink material for forming the second color conversion layer 520b together with a remainder of the ink material into the grooves 268. That is, the second color conversion layer 520b may extend from the second opening 267b to be positioned in the grooves 268 surrounding the second opening 267b.

As illustrated in FIG. 7, a portion of the partition wall 265 may be damaged during a process of manufacturing the color conversion panel 2000 of the display device according to an embodiment. The partition wall 265 is formed to have a height to accommodate the first color conversion layer 520a, the second color conversion layer 520b, and the transmission layer 520c. In addition, the partition wall 265 may have a narrow width in a direction along the color conversion panel 2000 since solid portions of the partition wall layer are positioned at a boundary between the first pixel PX1, the second pixel PX2, and the third pixel PX3. As such, since the partition wall 265 has a narrow width relative to a large height, there is a risk of being damaged during the process. In an embodiment, for example, a portion of the partition wall 265 positioned at one side of the second opening 267b, and closest to the second opening 267b, may be damaged. Since the partition wall 265 of the color conversion panel 2000 of the display device according to the embodiment includes the grooves 268, the ink material for forming the second color conversion layer 520b leaked from the second opening 267b due to the breakage of the partition wall 265 at the portion closest to the second opening 267b, may be accommodated in the grooves 268 and not be leaked into an adjacent opening. That is, the second color conversion layer 520b may be positioned in the grooves 268 surrounding the second opening 267b and in the second opening 267b.

As illustrated in FIG. 8, the partition wall 265 of the color conversion panel 2000 of the display device according to the comparative example may include a wall opening 269 for receiving the leaked ink. That is, the grooves 268 having a depth of about half the thickness of the partition wall 265 formed in the partition wall 265 in the color conversion panel 2000 of the display device according to the example. In contrast, the wall opening 269 having a depth corresponding to the thickness of the partition wall 265 may be formed in the partition wall 265 in the color conversion panel 2000 of the display device according to the comparative example. The comparative example is similar to the example in that the leaked ink can be accommodated in the wall opening 269. However, as the wall opening 269 is formed, a width of sub-walls of the partition wall 265 at opposing sides of the wall opening 260 may become narrower and may be more vulnerable to external force. The partition wall 265 of the color conversion panel 2000 of the display device according to the example may include the groove 268, thereby enabling the partition wall 265 to be more rigidly formed compared to the comparative example. Accordingly, a rate of occurrence of damage to the partition wall 265 may be reduced.

In addition, the partition wall 265 of the color conversion panel 2000 of the display device according to an embodiment may be made of a colored material. In an embodiment, for example, the partition wall 265 may include a black pigment or a blue pigment. Accordingly, the display device according to the example in which the partition wall 265 including the grooves 268 is formed at the boundary between the pixels is more effective in preventing light leakage between the pixels, compared to the comparative example in which the partition wall 265 including the wall opening 269 is formed at the boundary between the pixels.

In addition, in the comparative example, process difficulty may be increased in order to allow ultraviolet rays to penetrate narrowly and deeply to narrowly form the wall opening 269 relative to the relatively large thickness of the partition wall 265. In the example, ultraviolet rays do not penetrate an entire thickness of the partition wall 265 to form the grooves 268 in the partition wall 265, the process difficulty may be relatively reduced.

In this case, the volume of the groove 268 of the partition wall 265 may be about 23% of a volume occupied by at least one of the first color conversion layer 520a, the second color conversion layer 520b and the transmission layer 520c. This is a value in consideration of a degree to which light emitting performance is not affected even when a portion of the partition wall 265 is damaged and ink leaks into one of the grooves 268. The area occupied by the wall opening 269 needs to be reduced in order to form the wall opening 269 of the partition wall 265 of the comparative example at a similar level. Accordingly, a number of the wall openings 269 surrounding the first color conversion layer 520a, the second color conversion layer 520b, and the transmission layer 520c increases. Therefore, it is necessary to form more of the wall openings 269 having a smaller size, and thus the process difficulty may increase. In the example, the process difficulty may be relatively reduced by increasing the area of the grooves 268 formed in the partition wall 265 and reducing a number thereof.

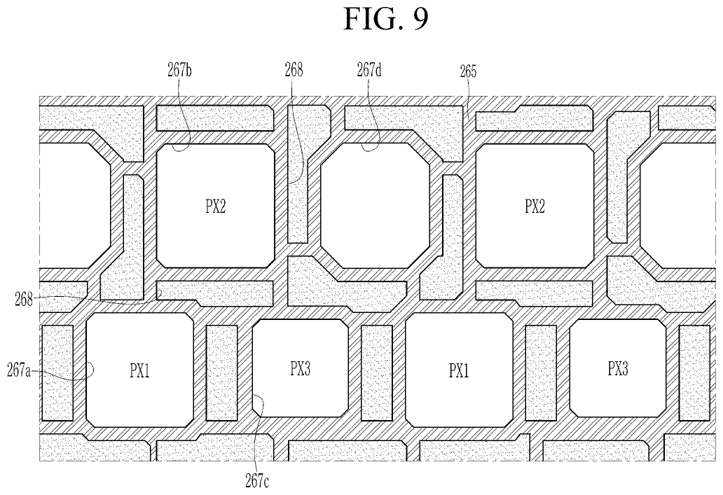

Next, a display device according to an embodiment will be described with reference to FIG. 9.

Since the display device according to the embodiment illustrated in FIG. 9 is substantially the same as the display device according to the embodiment shown in FIG. 1 to FIG. 5, a description of the same parts will be omitted. The present embodiment is different from the previous embodiment in that the number of grooves 268 of the partition wall 265 is smaller than that of the preceding embodiment, and will be further described below.

FIG. 9 illustrates a top plan view showing a color conversion panel 2000 of a display device according to an embodiment.

The display device according to the embodiment may include a display panel 1000 and a color conversion panel 2000 as in the previous embodiment.

As illustrated in FIG. 9, the partition wall 265 of the color conversion panel of the display device according to the embodiment may include openings 267a, 267b, 267c, and 267d and grooves 268. A planar shape of the openings 267a, 267b, 267c, and 267d in the present embodiment may be the same as those in the previous embodiment. A planar size and number of grooves 268 in the present embodiment may be different from those in the previous embodiment.

A pair of two grooves 268 in the preceding embodiment may be integrated into one groove 268 in the present embodiment. That is, in the present embodiment, the planar size of an individual one of the grooves 268 may be larger than in the preceding embodiment, and the total number of the grooves 268 may be smaller than in the preceding embodiment. In an embodiment, for example, the first opening 267a may be surrounded by seven grooves 268, the second opening 267b and third opening 267c may be surrounded by six grooves 268, and the fourth opening 267d may be surrounded by four grooves 268. However, this is only an example, and a number of grooves 268 surrounding each of the openings 267a, 267b, 267c, and 267d may be variously changed.

In the embodiment, process difficulty may be lowered by increasing the planar size of the grooves 268 formed in the partition wall 265 and reducing the number thereof.

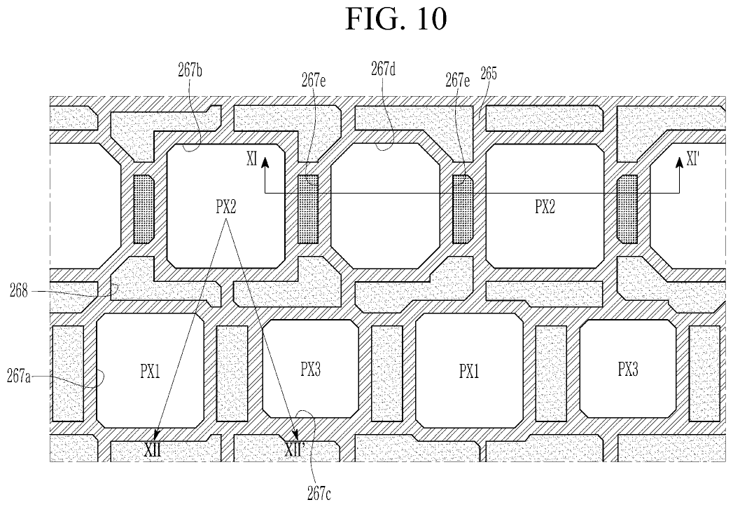

Next, a display device according to an embodiment will be described with reference to FIG. 10 to FIG. 12.

Since the display device according to the embodiment illustrated in FIG. 10 to FIG. 12 is substantially the same as the display device according to the embodiment shown in FIG. 1 to FIG. 5, a description of the same parts will be omitted. The present embodiment is different from the previous embodiment in that a fifth opening 267e is further formed, and will be further described below.

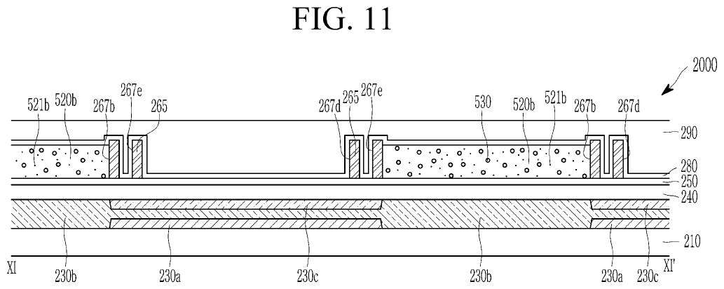

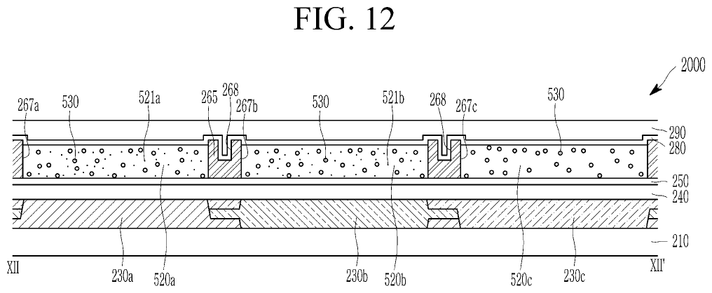

FIG. 10 illustrates a top plan view showing a color conversion panel 2000 of a display device according to an embodiment, FIG. 11 illustrates a cross-sectional view of a color conversion panel 2000 of a display device taken along line XI-XI′ of FIG. 10 according to an embodiment, and FIG. 12 illustrates a cross-sectional view of a color conversion panel 2000 of a display device taken along line XII-XII′ of FIG. 10 according to an embodiment.

The display device according to the embodiment may include a display panel 1000 and a color conversion panel 2000 as in the previous embodiment.

As illustrated in FIG. 10 to FIG. 12, the partition wall 265 of the color conversion panel 2000 of the display device according to the embodiment may include openings 267a, 267b, 267c, 267d, and 267e and grooves 268. The first opening 267a, the second opening 267b, the third opening 267c, and the fourth opening 267d in the present embodiment may be the same as those in the previous embodiment. In the present embodiment, the partition wall 265 may further include the fifth opening 267e. A position, size, and number of the grooves 268 in the present embodiment may be different from those in the previous embodiment.

The fifth opening 267e may be positioned between the second opening 267b and the fourth opening 267d. A color conversion layer pattern or a transmission layer pattern of a light control layer is not formed in the fourth opening 267d (e.g., is excluded from the fourth opening 267d). Accordingly, even when the partition wall 265 positioned between the second opening 267b and the fourth opening 267d is partially damaged and the ink material for forming the second color conversion layer 520b positioned in the second opening 267b is ejected into such opening, color mixing may not occur. Accordingly, the fifth opening 267e in the partition wall 265 may be positioned between the second opening 267b and the fourth opening 267d instead of the groove 268.

In an embodiment, the fifth opening 267e may be open in opposing directions along the thickness direction, and may penetrate the thickness of the partition wall 265. That is, the plurality of openings which is defined by the partition wall 265 further includes fourth opening 267d excluding the color conversion layer pattern and the transmission layer pattern, the fourth opening 267d overlapping the various color filters, the partition wall 265 further defines a plurality of sub-walls which are between the second opening 267b and the fourth opening 267d and spaced apart from each other by an opening portion (e.g., the fifth opening 267e) which is extended through a thickness of the partition wall 265 and is between the second opening 267b and the fourth opening 267d Within the partition wall 265, each of the opening portion (e.g., the fifth opening 267e) and the groove 268 has a depth, and the depth of the opening portion is greater than the depth of the groove 268.

In the present embodiment, the planar size of the grooves 268 may be larger than in the preceding embodiment, and the number of the grooves 268 may be smaller than in the preceding embodiment. In an embodiment, for example, the first opening 267a and the third opening 267c may each be surrounded by four grooves 268. The second opening 267b and the fourth opening 267d may be surrounded by four grooves 268 and two fifth openings 267e. However, this is merely an example, and the number of the grooves 268 surrounding each of the first opening 267a, the second opening 267b, the third opening 267c, and the fourth opening 267d, and the number of the fifth opening 267e are variously changed.

In the present embodiment, the grooves 268 may be formed by half-etching a thickness of some areas of the partition wall 265, and the fifth opening 267e may be formed by full-etching the thickness of some areas of the partition wall 265. Accordingly, the groove 268 may have a depth of about half a total (or maximum) thickness of the partition wall 265, and the fifth opening 267e may have a depth corresponding to the total thickness of the partition wall 265. That is, the depth of the fifth opening 267e may be greater than the depth of the groove 268 along a thickness direction.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A color conversion panel comprising:
a partition wall defining:
an opening, and
a groove in the partition wall and surrounding the opening; and
a color conversion layer and a transmission layer within the opening which is defined by the partition wall.

2. The color conversion panel of claim 1, wherein
the partition wall has a thickness adjacent to the groove,
the groove has a depth, and
the depth of the groove which is in the partition wall is about ⅓ or more and about ½ or less of the thickness of the partition wall which is adjacent to the groove.

3. The color conversion panel of claim 1, wherein
the partition wall has a thickness corresponding to the groove and a thickness adjacent to the groove, and
the thickness of the partition wall which corresponds to the groove is about ½ or more and about ⅔ or less of the thickness of the partition wall which is adjacent to the groove.

4. The color conversion panel of claim 3, wherein
the color conversion layer which is within the opening defined by the partition wall has a thickness,
the thickness of the partition which is adjacent to the groove is about 10 micrometers or more,
the thickness of the partition which corresponds to the groove is about 5 micrometers or more, and
the thickness of the color conversion layer is about 9 micrometers or more.

5. The color conversion panel of claim 1, wherein
the groove which is in the partition wall is provided in plural including a plurality of grooves, and
the opening which is defined by the partition wall is surrounded by the plurality of grooves.

6. The color conversion panel of claim 1, wherein
each of the groove which is in the partition wall, and the color conversion layer, has a volume, and
the volume of the groove is about 23% or less of the volume of the color conversion layer.

7. The color conversion panel of claim 1, further comprising:
a color filter layer including a first color filter and a second color filter,
the opening which is defined by the partition wall is provided in plural including a plurality of openings, the plurality of openings comprising:
a first opening corresponding to the first color filter, and
a second opening corresponding to the second color filter, and
a light control layer including:
the color conversion layer within the first opening which is defined by the partition wall, and
the transmission layer within the second opening which is defined by the partition wall.

8. The color conversion panel of claim 7, wherein
the first opening which is defined by the partition wall does not overlap the second color filter, and
the second opening which is defined by the partition wall does not overlap the first color filter.

9. The color conversion panel of claim 8, wherein the partition wall overlaps the first color filter or the second color filter.

10. The color conversion panel of claim 7, wherein the plurality of openings which is defined by the partition wall further comprises a third opening excluding the color conversion layer and the transmission layer, the third opening overlapping the first color filter or the second color filter.

11. The color conversion panel of claim 10, wherein
the partition wall further defines a plurality of sub-walls which are between the first opening and the third opening,
the plurality of sub-walls are spaced apart from each other by an opening portion which is extended through a thickness of the partition wall and is between the first opening and the third opening, and
within the partition wall:
each of the opening portion and the groove has a depth, and
the depth of the opening portion is greater than the depth of the groove.

12. A display device comprising:
a partition wall defining:
an opening, and
a groove in the partition wall and surrounding the opening;
a color conversion layer in the opening which is defined by the partition wall;
an organic light emitting element which faces the color conversion layer; and
a transistor connected to the organic light emitting element.

13. The display device of claim 12, wherein
the partition wall has a thickness adjacent to the groove,
the groove has a depth, and
the depth of the groove is about ⅓ or more and about ½ or less of the thickness of the partition wall which is adjacent to the groove.

14. The display device of claim 12, wherein
the partition wall has a thickness corresponding to the groove and a thickness adjacent to the groove, and
the thickness of the partition wall which corresponds to the groove is about ½ or more and about ⅔ or less of the thickness of the partition wall which is adjacent to the groove.

15. The display device of claim 14, wherein
the color conversion layer which is within the opening defined by the partition wall has a thickness,
the thickness of the partition which is adjacent to the groove is about 10 micrometers or more,
the thickness of the partition which corresponds to the groove is about 5 micrometers or more, and
the thickness of the color conversion layer is about 9 micrometers or more.

16. The display device of claim 12, wherein
the groove which is in the partition wall is provided in plural including a plurality of grooves, and
the opening which is defined by the partition wall is surrounded by the plurality of grooves.

17. The display device of claim 12, wherein
each of the groove which is in the partition wall, and the color conversion layer, has a volume, and
the volume of the groove is about 23% or less of the volume of the color conversion layer.

18. The display device of claim 12, further comprising:
a color filter layer comprising a first color filter and a second color filter,
the opening which is defined by the partition wall provided in plural including a plurality of openings, the plurality of openings comprises:
a first opening corresponding to the first color filter, and
a second opening corresponding to the second color filter,
the color conversion layer including:
a color conversion material layer within the first opening which is defined by the partition wall, and
a transmission layer within the second opening which is defined by the partition wall.

19. The display device of claim 18, wherein
the first opening which is defined by the partition wall does not overlap the second color filter,
the second opening which is defined by the partition wall does not overlap the first color filter, and
the partition wall overlaps the first color filter or the second color filter.

20. The display device of claim 18, wherein
the plurality of openings which is defined by the partition wall further comprises a third opening excluding the color conversion layer, the third opening overlapping the first color filter or the second color filter,
the partition wall further defines a plurality of sub-walls which are between the first opening and the third opening,
the plurality of sub-walls are spaced apart from each other by an opening portion which is extended through a thickness of the partition wall and is between the first opening and the third opening, and
within the partition wall:
each of the opening portion and the groove has a depth, and
the depth of the opening portion is greater than the depth of the groove.
